(19) United States
(12) Patent Application Publication
(10) Pub. No.: US 2008/0080160 A1
(43) Pub. Date: Apr. 3, 2008

(54) EMI SHIELDING ASSEMBLIES

(75) Inventors: Gerald Robert English, Glen Ellyn, IL (US); Allan Richard Zuehlsdorf, Sycamore, IL (US); Peter John Doyle, Los Altos, CA (US); Aleksey Pirkhalo, Chicago, IL (US)

Correspondence Address: HARNESS, DICKEY, & PIERCE, P.L.C, 7700 BONHOMME, STE 400, ST. LOUIS, MO, 63105, US

(73) Assignee: Laird Technologies, Inc., Chesterfield, MO (US)

(21) Appl. No.: 11/838,801

(22) Filed: Aug. 14, 2007

Related U.S. Application Data
(63) Continuation-in-part of application No. 11/514,071, filed on Aug. 31, 2006.
(63) Continuation-in-part of application No. 11/431,847, filed on May 10, 2006, now Pat. No. 7,262,369.
(63) Continuation-in-part of application No. 29/244,955, filed on Dec. 16, 2005, now Pat. No. D548738.
(63) Continuation-in-part of application No. 29/244,956, filed on Dec. 16, 2005, now Pat. No. D549231.
(63) Continuation-in-part of application No. 29/244,957, filed on Dec. 16, 2005, now Pat. No. D549706.
(60) Provisional application No. 60/854,527, filed on Oct. 26, 2006.

(51) Int. Cl. H05K 9/00

(52) U.S. Cl. 361/818

(57) ABSTRACT

In one exemplary embodiment, an EMI shield assembly generally includes a frame adapted to be secured to a mounting surface, a cover attachable to the frame, and at least one resilient electrically-conductive member disposed on an inner side of the cover. The at least one resilient electrically-conductive member may be configured to contact at least one electrically-conductive surface on the mounting surface, to establish a current-conducting path from the electrically-conductive surface to the cover when the cover is attached to the frame. The at least one resilient electrically-conductive member may be configured to be compressed against at least one electrically-conductive surface on the mounting surface when the cover is attached to the frame. This compression may help provide an effective amount of contact pressure against the at least one electrically-conductive surface to establish a predetermined or desirable level of electrical conductivity.

### CROSS-REFERENCE TO RELATED APPLICATIONS

This application is a continuation-in-part of U.S. patent application Ser. No. 11/514,071 filed Aug. 31, 2006.

This application is a continuation-in-part of allowed U.S. patent application Ser. No. 11/431,847 filed May 10, 2006.

This application is a continuation-in-part of U.S. patent application No. 29/244,955 filed Dec. 16, 2005 (now U.S. Design Pat. No. D548,738 issued Aug. 14, 2007).

This application is a continuation-in-part of allowed U.S. patent application No. 29/244,956 filed Dec. 16, 2005.

This application is a continuation-in-part of allowed U.S. patent application No. 29/244,957 filed Dec. 16, 2005.

This application claims the benefit of U.S. Provisional Application No. 60/854,527 filed Oct. 26, 2006.

The disclosures of the above applications are incorporated herein by reference.

### FIELD

The present disclosure generally relates to multi-piece shields for shielding components on a printed circuit board from electromagnetic interference (EMI)/radio frequency interference (RFI).

### BACKGROUND

The statements in this section merely provide background information related to the present disclosure and may not constitute prior art.

Electronic equipment includes electrical components and circuits mounted on a substrate that can be sensitive to electromagnetic interference (EMI) and radio frequency interference (RFI). Such EMI/RFI interference may originate from internal sources within the electronic equipment or from external EMI/RFI interference sources. Interference can cause degradation or complete loss of important signals, thereby rendering the electronic equipment inefficient or inoperable. Accordingly, the circuits (sometimes referred to as RF modules or transceiver circuits) usually require EMI/RFI shielding in order to function properly. The shielding reduces interference not only from external sources, but also from various functional blocks within the module.

As used herein, the term “EMI” should be considered to generally include and refer to EMI emissions and RFI emissions, and the term “electromagnetic” should be considered to generally include and refer to electromagnetic and radio frequency from external sources and internal sources. Accordingly, the term shielding (as used herein) generally includes and refers to EMI shielding and RFI shielding, for example, to prevent (or at least reduce) ingress and egress of EMI and RFI relative to a housing or other enclosure in which electronic equipment is disposed.

By way of example, electronic circuits or components of a printed circuit board (PCB) are often enclosed with shields to localize EMI within its source, and to insulate other devices proximal to the EMI source. Such shields may be soldered or otherwise affixed to the PCB, thus increasing the overall size of the PCB. Soldered shields, however, may need to be removed to repair or replace the covered component, which can be an expensive and time consuming task that can even cause damage to the PCB.

### SUMMARY

According to various aspects of the present disclosure, exemplary embodiments are provided of assemblies suitable for providing EMI shielding and electrical conduction. In one exemplary embodiment, an assembly generally includes a frame adapted to be secured to a mounting surface, a cover attachable to the frame, and at least one resilient electrically-conductive member disposed on an inner side of the cover. The at least one resilient electrically-conductive member is configured to contact at least one electrically-conductive surface on the mounting surface, to establish a current-conducting path from the electrically-conductive surface to the cover when the cover is attached to the frame.

In some embodiments, the at least one resilient electrically-conductive member forms at least one interior partition wall that defines a plurality of shielding compartments. The at least one interior partition wall may be formed entirely by the at least one resilient electrically-conductive member independent of the cover.

In some embodiments, the at least one resilient electrically-conductive member is configured to be compressed against at least one electrically-conductive surface on the mounting surface when the cover is attached to the frame. The compression of the at least one resilient electrically-conductive member may provide an effective amount of contact pressure against the at least one electrically-conductive surface to establish at least a predetermined or desirable level of electrical conductivity between the cover and the electrically-conductive surface, such as a trace on a circuit board, etc.

In some embodiments, the frame has one or more side walls adapted to be secured to a mounting surface, which side walls include protuberances and/or retaining apertures. The electrically-conductive cover also has one or more side walls having protuberances and/or retaining apertures configured for releasably attaching the cover by engaging the corresponding protuberances or retaining apertures of the frame.

Some embodiments include EMI shield assemblies having at least one resilient electrically-conductive member. The at least one electrically-conductive member intervenes between one or more areas, so as to partition the space covered by the assembly to provide for a reduced level of attenuation of transfer of electromagnetic energy from the one or more partitioned areas. In one or more of these exemplary embodiments, partitioned areas may be defined by an elastomer member, whereby EMI shielding is provided to one or more electrical components located within each partitioned area.

Further aspects and features of the present disclosure will become apparent from the detailed description provided hereinafter. In addition, any one or more aspects of the present disclosure may be implemented individually or in any combination with any one or more of the other aspects of the present disclosure. It should be understood that the detailed description and specific examples, while indicating exemplary embodiments of the present disclosure, are intended for purposes of illustration only and are not intended to limit the scope of the present disclosure.

### DRAWINGS

The drawings described herein are for illustration purposes only and are not intended to limit the scope of the present disclosure in any way.

FIG. 1 is an exploded perspective view of an EMI shield assembly that includes a frame, a cover, and an elastomeric component according to exemplary embodiments;

FIG. 2 is a cross-sectional side elevation view of the EMI shield cover shown in FIG. 1 and illustrating the elastomeric component attached to the cover according to exemplary embodiments;

FIG. 3 is an outer perspective view of the EMI shield assembly shown in FIG. 1 with the cover attached to the frame according to exemplary embodiments;

FIG. 4 is an inner perspective view of the EMI shield assembly shown in FIG. 3;

FIG. 5 is an upper plan view of the EMI shield assembly shown in FIG. 3;

FIG. 6 is a lower plan view of the EMI shield assembly shown in FIG. 3;

FIG. 7 is a front elevation view of the EMI shield assembly shown in FIG. 3;

FIG. 8 is a rear elevation view of the EMI shield assembly shown in FIG. 3;

FIG. 9 is a left elevation view of the EMI shield assembly shown in FIG. 3;

FIG. 10 is a right elevation view of the EMI shield assembly shown in FIG. 3;

FIG. 11 is an outer perspective view of the cover of the EMI shield assembly shown in FIGS. 1 through 10;

FIG. 12 is an inner perspective view of the cover shown in FIG. 11;

FIG. 13 is an upper plan view of the cover shown in FIG. 11;

FIG. 14 is a lower plan view of the cover shown in FIG. 11;

FIG. 15 is a front elevation view of the cover shown in FIG. 11;

FIG. 16 is a rear elevation view of the cover shown in FIG. 11;

FIG. 17 is a left elevation view of the cover shown in FIG. 11;

FIG. 18 is a right elevation view the cover shown in FIG. 11;

FIG. 19 is an outer perspective view of the frame of the EMI shield assembly shown in FIGS. 1 through 10;

FIG. 20 is an inner perspective view of the frame shown in FIG. 19;

FIG. 21 is an upper plan view of the frame shown in FIG. 19;

FIG. 22 is a lower plan view of the frame shown in FIG. 19;

FIG. 23 is a front elevation view of the frame shown in FIG. 19;

FIG. 24 is a rear elevation view of the frame shown in FIG. 19;

FIG. 25 is a left elevation view of the frame shown in FIG. 19;

FIG. 26 is a right elevation view of the frame shown in FIG. 19; and

FIG. 27 is an exemplary line graph illustrating attenuation of EMI (in decibels) versus frequency for three exemplary EMI shielding assemblies.

### DETAILED DESCRIPTION

The following description is merely exemplary in nature and is in no way intended to limit the present disclosure, application, or uses. It should be understood that throughout the drawings, corresponding reference numerals indicate like or corresponding parts and features.

The present application discloses various embodiments of EMI shielding assemblies having a frame adapted to be secured to a board, and a cover attachable to the frame. In some exemplary embodiments, one or more resilient or flexible members (e.g., electrically-conductive elastomeric members or components, etc.) are disposed (e.g., overmolded onto, molded-in-place, adhesively bonded, welded, etc.) on an inner side of the cover. When the cover is attached to the frame, the resilient or flexible members may establish contact and electrical conductivity with at least one electrically-conductive surface (e.g., traces, etc.) on the board or substrate (e.g., printed circuit board, etc.) to which the frame is attached (e.g., soldered, etc.).

In some exemplary embodiments, an EMI shield assembly generally includes a frame adapted to be secured to a mounting surface, a cover attachable to the frame, and at least one flexible electrically-conductive member disposed on an inner side of the cover. The at least one flexible electrically-conductive member is configured to be compressed against at least one electrically-conductive surface on the mounting surface (e.g., trace on a circuit board, etc.) when the cover is attached to the frame. This compression of the at least one flexible electrically-conductive member may provide an effective amount of contact pressure against the at least one electrically-conductive surface to establish at least a predetermined or desirable level (and in some embodiments, at least a minimally sufficient level) of electrical conductivity between the cover and the electrically-conductive surface.

In some exemplary embodiments, one or more resilient or flexible members form one or more interior partition walls that define a plurality of shielding compartments. The one or more interior partition walls may be formed entirely by the one or more resilient or flexible electrically-conductive members, independent of the cover configuration. Advantageously, this may thus allow the same cover configuration to be used, for example, for two different circuit board layouts. For example, first and second covers both having the same cover configuration (e.g., stamped configuration, etc.) may then be provided with elastomer rib members that are molded-in-place or over-molded to the first and second covers. But the first and second covers need not be provided with elastomer rib members in an identical arrangement. Instead, the first cover may be provided with one or more elastomer rib members that define one or more interior partition walls (and shielding compartments defined thereby) in a different arrangement than that associated with the second cover. Accordingly, this allows the same cover configuration to be tailored or customized by way of the elastomer rib members (and the interior partition walls and compartment defined thereby) to a number of different shielding configurations corresponding to a number of different circuit board layouts.

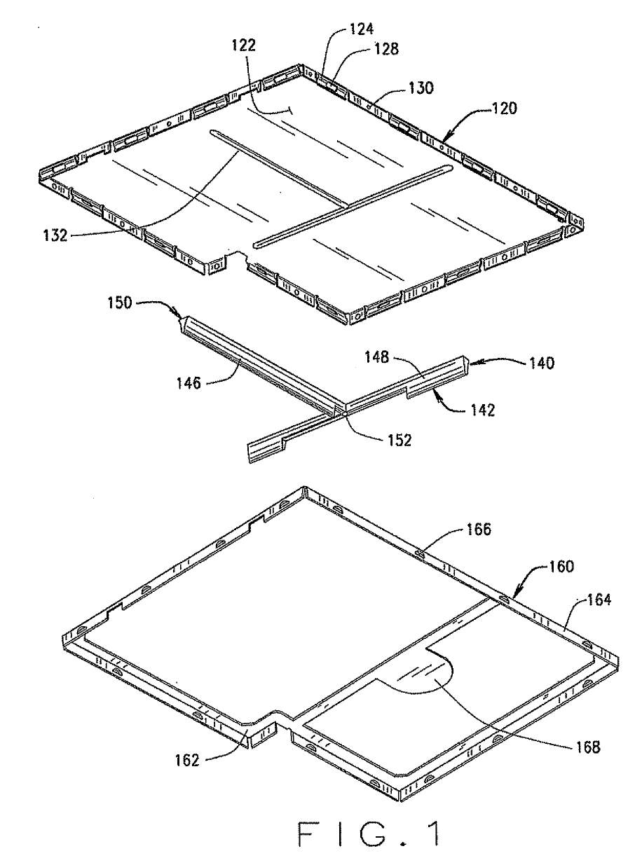

FIG. 1 shows an exploded assembly view of an exemplary EMI shielding assembly 100 embodying one or more aspects of the present disclosure. As shown, the EMI shielding assembly 100 generally includes a lid or cover 120. The assembly 100 also includes a base member or frame 160 to which the cover 120 is attachable.

The frame 160 is adapted to be secured to a mounting surface (e.g., circuit board, etc.). The frame 160 includes an upper planar surface with at least one opening 170 therein. The cover 120 includes side walls 124 configured to releasably attach the cover to the frame 160 and also to allow for relatively easy or ready removal of the cover 120 from the frame 160.

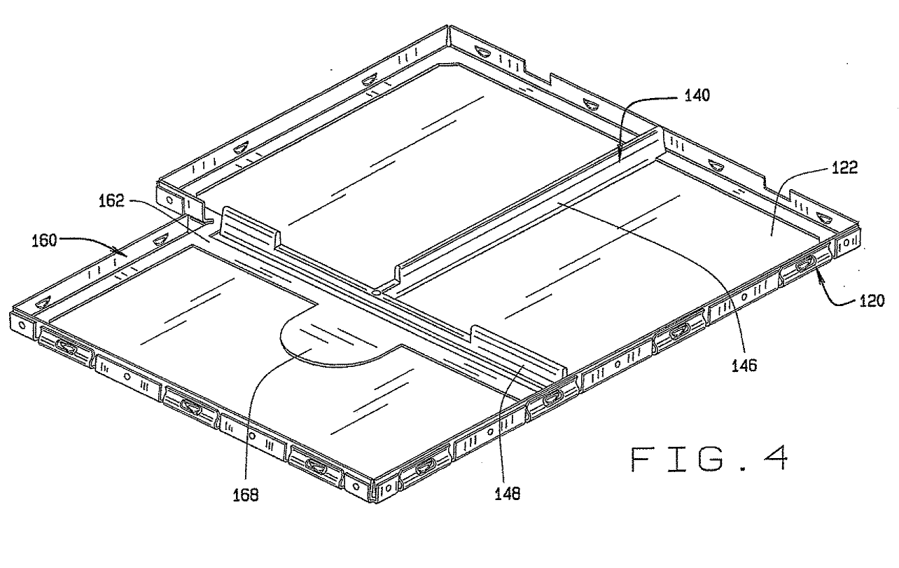

As shown in FIG. 4, the assembly 100 further includes at least one resilient flexible rib member 140 disposed on a portion of the inner side 122 of the cover 120. The flexible rib member 140 is configured (e.g., dimensioned, etc.) to have a height greater than the distance between the surface on which the frame 160 is mounted and the cover's inner surface 122 when attached to the frame 160. This relative sizing thus allows for compression of the flexible rib member 140 by the attached cover 120. The flexible member 140 is also electrically-conductive. The compression of the flexible member 140 preferably produces a sufficient contact pressure effective for establishing at least a certain or desirable level (e.g., a minimally sufficient level in some embodiments, etc.) of electrical conductivity between at least one conductive surface (e.g., traces, etc.) on the board to which the frame 160 is mounted and the cover 120, through the flexible member 140.

When disposed over one or more electronic components of a circuit board, for example, the assembly 100 provides EMI shielding of the electronic component(s). The assembly 100 is capable of shielding electronic component(s) from EMI/RFI emitted from other electronic components, and/or inhibiting EMI/RFI emitted by the electronic component(s) from interfering with other components. The assembly 100 can be used with a wide range of electronic components and packages, such as integrated circuits mounted on a printed circuit board, etc.

With continued reference to FIG. 1, the frame 160 is adapted to be mounted or secured to a substrate, such as a circuit board, etc. The frame 160 (or outer portion thereof) is electrically-conductive. The frame 160 includes a generally planar upper surface 162 and one or more side walls 164. The side walls 164 may be preferably adapted to be secured to a circuit board. The frame's planar upper surface 162 may include one or more openings 170 therein. By way of example, the upper surface area 162 may provide access to one or more electronic components located within the area covered by the assembly 100 after the cover 120 has been removed from the frame 160.

In the illustrated embodiment, the frame's side walls 164 include protuberances 166. The protuberances 166 are configured to align with and be retained by corresponding openings 128 of the cover 120. In alternative embodiments, the frame 160 may comprise one or more retaining openings (e.g., recesses, voids, cavities, slots, grooves, holes, depressions, combinations thereof, etc.) configured to align with and engagingly receive one or more protuberances (e.g., catches, snaps, latches, tabs, detents, protuberances, protrusions, ribs, ridges, ramp-ups, darts, lances, dimples, half-dimples, combinations thereof, etc.) of a cover. In still other embodiments, the frame's side walls may include one or more retaining apertures and one or more protuberances. Alternatively, other means can be employed for attaching the frame to the cover besides the engagement of protuberances within openings.

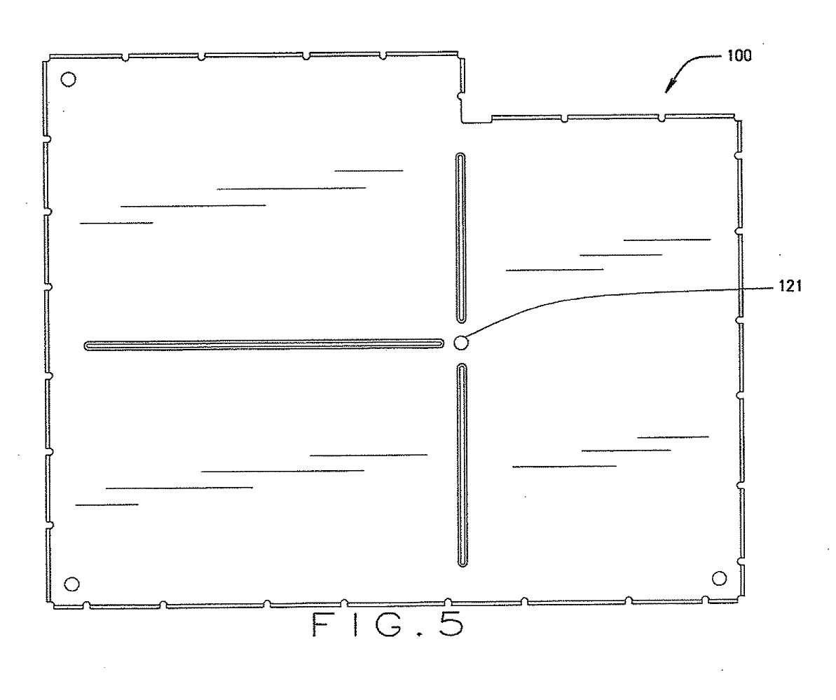

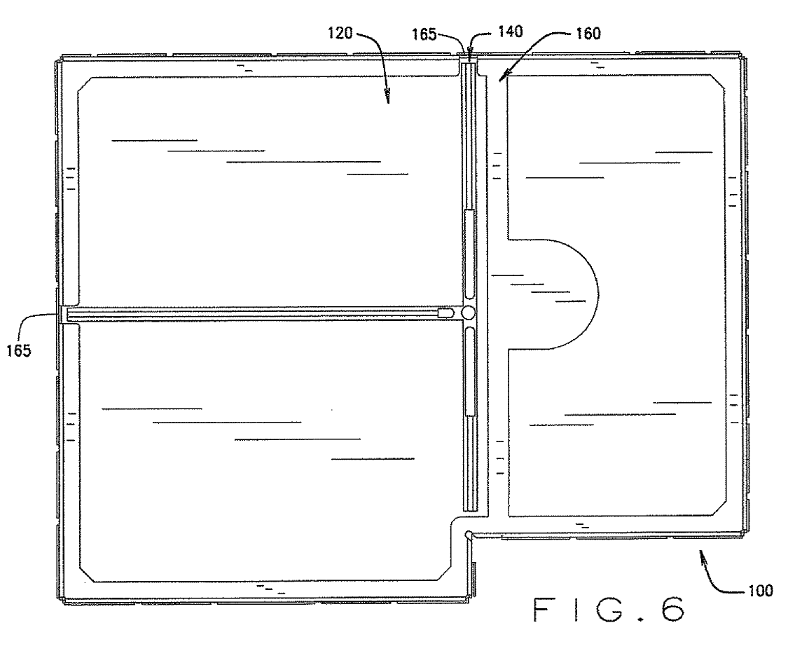

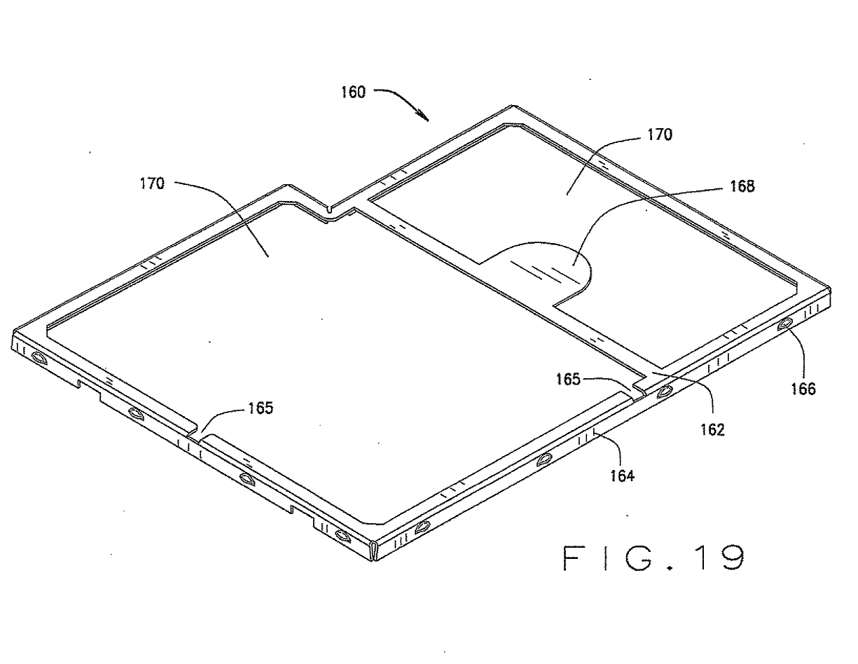

As shown in FIGS. 6 and 19, the frame 160 may also include notches or cutout portions 165. These notches or cutouts 165 can be configured (e.g., positioned, dimensionally sized, shaped, etc.) to provide sufficient clearance such that the elastomeric member 140 does not interfere with the frame 160. For example, the notches or cutouts 165 can provide clearance such that the elastomeric member 140 doesn't contact the frame 160 as the cover 120 is being installed on the frame 160, where that contact might otherwise inhibit installation. Some exemplary embodiments are configured such that there is a clearance of about 0.15 millimeters between the frame 160 and the elastomeric member 140. Alternatively, other embodiments may include a larger clearance or a smaller clearance.

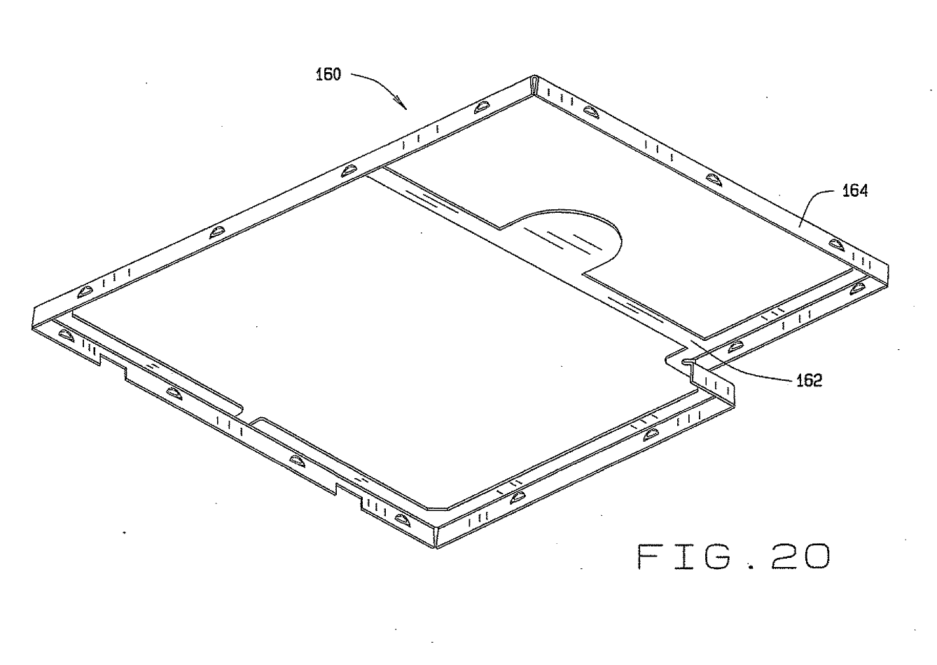

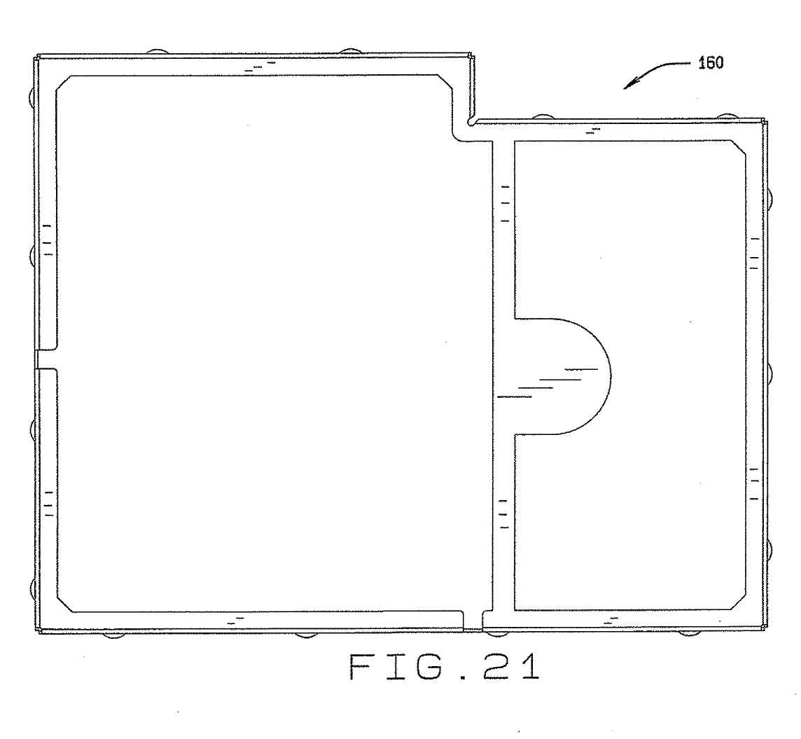

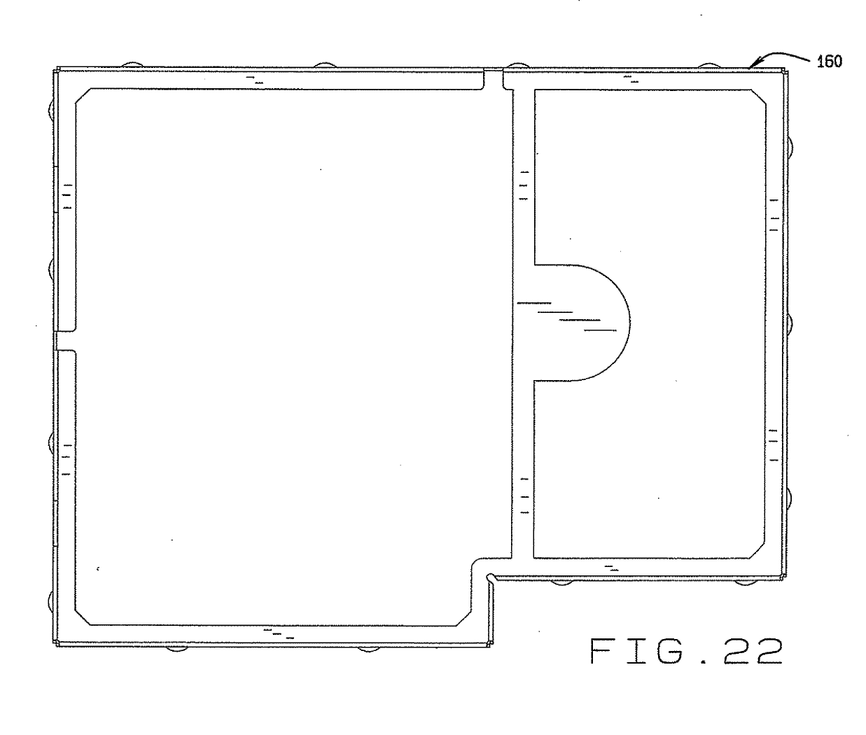

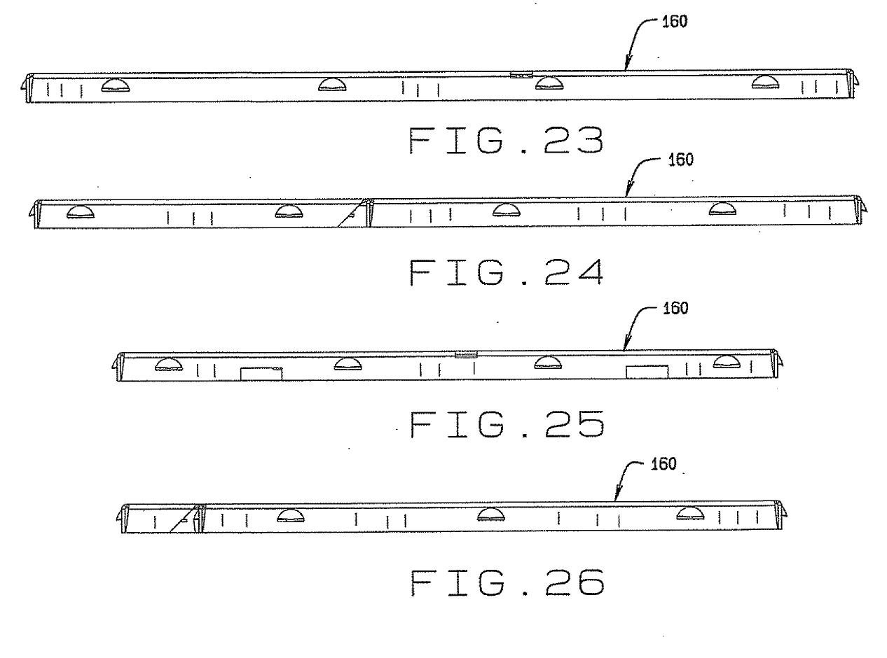

In various embodiments, the frame 160 may be integrally or monolithically formed as a single component. In this particular embodiment, the frame 160 may be formed by stamping in a piece of material a flat profile pattern for the frame 160. For the particular illustrated embodiment, the stamped profile for the frame 160 may include openings 170, notches or cutouts 165, and tabs. After stamping the flat pattern profile for the frame 160 into the piece of material, the wall portions may then be folded, bent, or otherwise formed so as to be generally perpendicular as shown in FIGS. 19 through 26. Even though the frame 160 may be formed integrally in this example, such is not required for all embodiments. For example, other embodiments of the frame may include tabs or wall portions that are discrete components separately attached to the frame, for example, by welding, adhesives, among other suitable methods. Alternative configurations (e.g., shapes, sizes, etc.), materials, and manufacturing methods (e.g., drawing, etc.) can be used for making the frame 160.

A wide range of materials may be used for the frame 160, such as nickel-silver alloys, copper-nickel alloys, cold rolled steel, stainless steel, tin-plated cold rolled steel, tin-plated copper alloys, carbon steel, brass, copper, aluminum, copper-beryllium alloys, phosphor bronze, steel, combinations thereof, among other suitable electrically-conductive materials. In one exemplary embodiment, a frame 160 is formed from a sheet of nickel alloy or cold rolled steel having a thickness of about 0.20 millimeters (with a tolerance of about +/−0.02 millimeters). The materials and dimensions provided herein are for purposes of illustration only, as the assembly and components thereof can be configured from different materials and/or with different dimensions depending, for example, on the particular application, such as the component to be shielded, space considerations within the overall apparatus, EMI shielding and heat dissipation needs, and other factors.

The cover 120 is configured to be releasably attached to the frame 160, in a manner that permits the cover 120 to be fairly easily removed and replaced onto the frame 160. As shown in FIG. 1, the cover 120 includes a generally planar upper surface having an inner side 122. The cover 120 also includes side walls 124 depending from the upper planar surface. The side walls 124 include retaining apertures 128 configured to engagingly receive the corresponding protuberances 166 of the frame 160, to thereby releasably attach the cover 120 to the frame 160. In alternative embodiments, the cover 120 may comprise one or more protuberances (e.g., catches, snaps, latches, tabs, detents, protuberances, protrusions, ribs, ridges, ramp-ups, darts, lances, dimples, half-dimples, combinations thereof, etc.) configured to align with and engage within one or more openings (e.g., recesses, voids, cavities, slots, grooves, holes, depressions, combinations thereof, etc.) of a frame. In still other embodiments, the cover's side walls may include one or more retaining apertures and one or more protuberances. Alternatively, other means can be employed for attaching the cover to the frame besides the engagement of protuberances within openings.

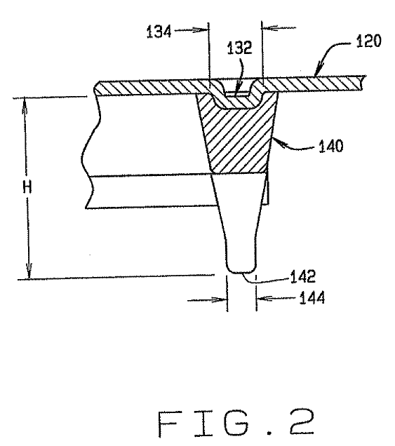

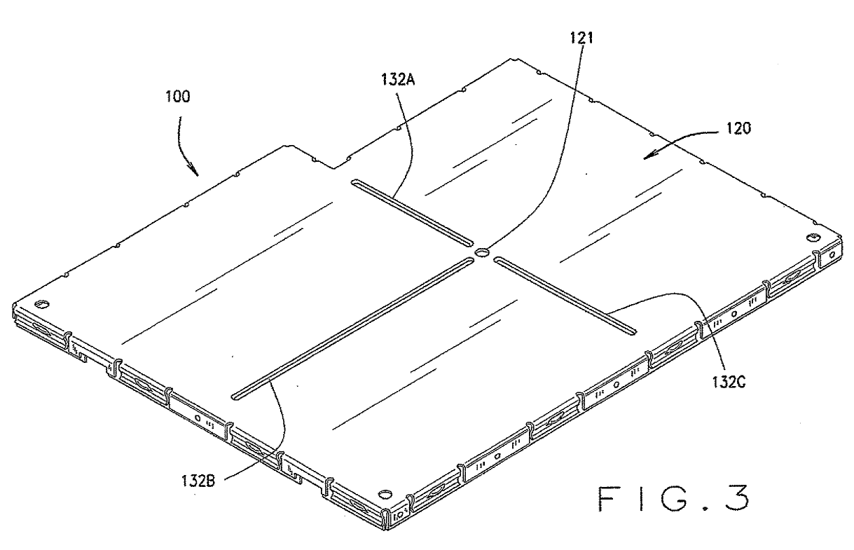

As shown in FIG. 3, the cover 120 may further comprise one or more support rib members 132A, 132B, and 132C formed in the cover 120. As shown in FIG. 2, the support rib members 132 have a width 134, which in one exemplary embodiment is about 0.60 millimeters (with a tolerance of about +/−0.10 millimeters). Other embodiments, however, may have wider or narrower support ribs.

The support rib members 132 may be integrally formed into the cover 120. Alternatively, one or more of the support rib members 132 may be individually formed as separate support rib portions.

The support rib members 132 may be configured to help stiffen or reinforce the upper portion of the cover 120, for example, to maintain the upper surface of the cover 120 in a generally straight, planar configuration. The one or more support rib members 132, together with the flexible rib member 140, may also cooperatively form or define one or more partitioned EMI shielding areas or enclosures. The support rib members 132 may also provide means for locating or affixing the flexible rib members 140 on the inner side 122 of the cover 120, which accordingly may provide for establishing partitioned areas under the cover.

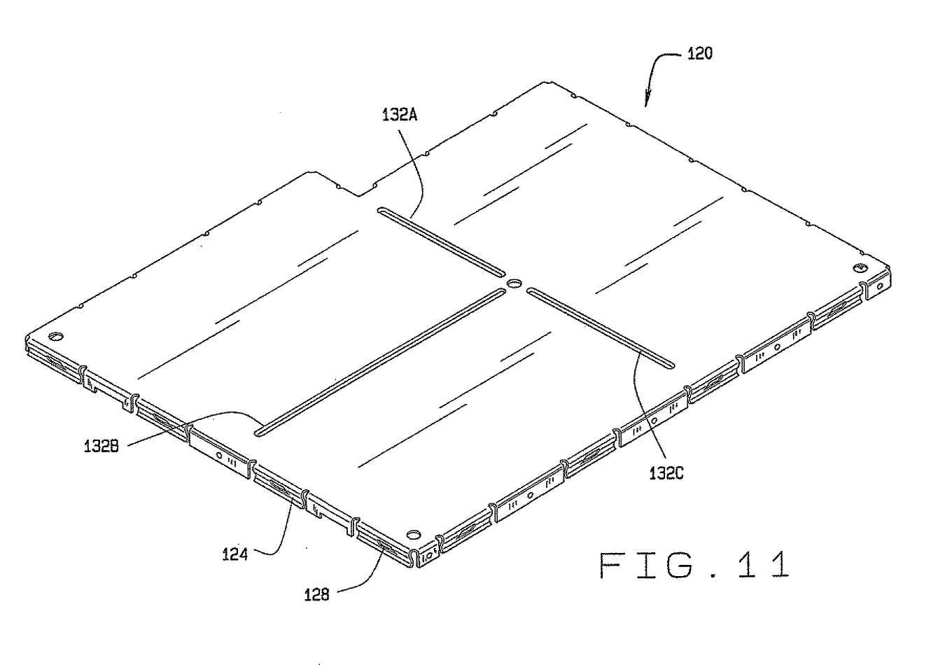

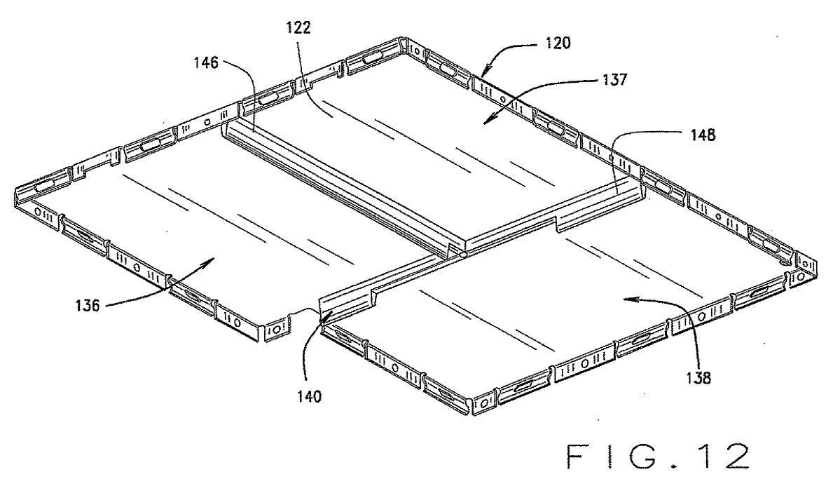

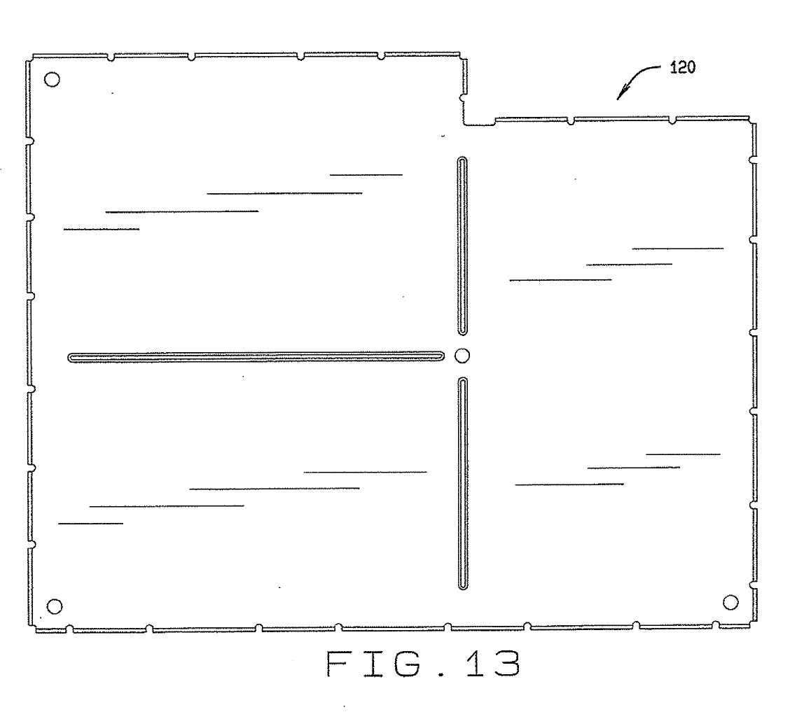

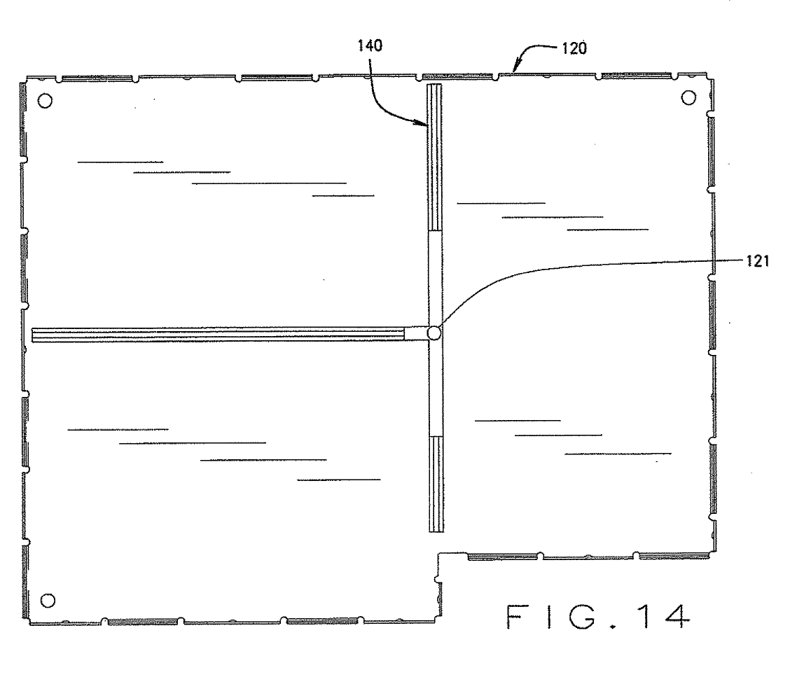

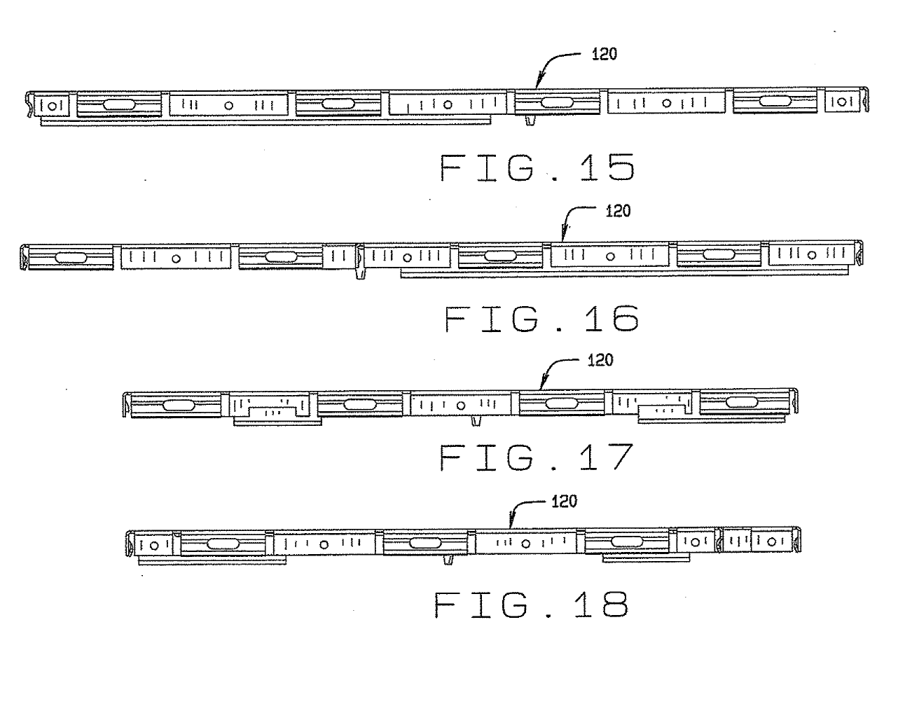

In various embodiments, the cover 120 may be integrally or monolithically formed as a single component. In this particular embodiment, the cover 120 may be formed by stamping in a piece of material a flat profile pattern for the cover 120. For the particular illustrated embodiment, the stamped profile for the cover 120 includes retaining apertures 128, detents 130, and may further include tabs. After stamping the flat pattern profile for the cover 120 into the piece of material, the wall portions may then be folded, bent, or otherwise formed so as to be generally perpendicular as shown in FIGS. 11 through 18. Even though the cover 120 may be formed integrally in this example, such is not required for all embodiments. For example, other embodiments may include tabs, wall portions, and/or protuberances that are discrete components separately attached to the cover 120, for example, by welding, adhesives, among other suitable methods. Alternative configurations (e.g., shapes, sizes, etc.), materials, and manufacturing methods (e.g., drawing, etc.) can be used for making the cover 120.

A wide range of materials may be used for the cover 120, such as nickel-silver alloys, copper-nickel alloys, cold rolled steel, stainless steel, tin-plated cold rolled steel, tin-plated copper alloys, carbon steel, brass, copper, aluminum, copper-beryllium alloys, phosphor bronze, steel, combinations thereof, among other suitable electrically-conductive materials. In one exemplary embodiment, a cover 120 is formed from a sheet of nickel alloy having a thickness of about 0.13 millimeters. In another exemplary embodiment, a cover 120 is formed from a sheet of stainless steel having a thickness of about 0.15 millimeters (with a tolerance of +/−0.02 millimeters). The materials and dimensions provided herein are for purposes of illustration only, as the assembly and components thereof can be configured from different materials and/or with different dimensions depending, for example, on the particular application, such as the component to be shielded, space considerations within the overall apparatus, EMI shielding and heat dissipation needs, and other factors.

The frame 160 and/or the cover 120 may be configured to allow for handling by pick-and-place equipment (e.g., vacuum pick-and-place equipment, etc.). For example, FIG. 1 shows a pick-up area 168 on the frame 160. In some embodiments, the frame 160 may also include tabs at the corners and/or along the side walls. The pick-up area 168 and/or tabs may facilitate handling of the frame 160, for example, during fabrication of the frame 160 or cover 120 through a progressive die stamping process. Alternatively, other manufacturing methods can also be used for making the frame 160.

Accordingly, some embodiments include a frame and a cover that may each be individually handled by pick-and-place equipment. After the cover has been assembled to the frame, the cover and frame may be collectively handled by pick-and-place equipment via the frame or cover's pick-up area.

FIGS. 1 through 26 illustrate the frame 160 and cover 120 according to a particular exemplary embodiment. Alternative embodiments can include a frame and/or a cover having more or less than peripheral walls and/or peripheral walls in a different configuration (e.g., rectangular configurations, non-rectangular configurations, triangular, hexagonal, circular, other polygonal shapes, etc.) than what is shown in the figures, etc. Further embodiments may include peripheral walls having more or less openings and/or protuberances than what are disclosed in the figures.

With further reference to FIG. 1, the elastomer member 140 may be disposed on an inner surface 122 of the cover 120. In this particular embodiment, the elastomer member 140 is resiliently compressible and also electrically-conductive. As shown in FIG. 1, the electrically-conductive elastomeric material 140 forms one or more ribs or walls 142. The ribs or walls 142 may be dispensed onto (e.g., via form-in-place dispensing equipment, hand-held dispenser or caulk gun, etc.), molded onto (e.g., overmolded, etc.) or attached (e.g., adhesively attached, etc.) to various portions of the cover 120. By way of example only, the electrically-conductive elastomeric member 140 may be dispensed onto the cover 120, or the electrically-conductive elastomeric member 140 may be over-molded onto the cover 120 through an insert-molding process.

In the illustrated embodiment, the cover 120 includes a through-hole 121 that may be used for injection molding of the elastomer through the hole 121 from the top side (after the cover 120 is inserted into a mold). This, in turn, may allow elastomer to be injection molded without any parting or injection lines in some embodiments.

The electrically-conductive elastomeric member 140 may be formed from various materials. In some preferred embodiments, the member 140 is formed from elastomeric materials filled with electrically-conductive particles. Examples of preferred elastomeric materials include silicone, fluorosilicone, fluorocarbon, and Ethylene Propylene Diene Monomer [EPDM]. Thermoplastic elastomer may also be used as the elastomeric material. Examples of preferred electrically-conductive particles include silver coated glass particles, which may be used to make an elastomeric material electrically-conductive. In other embodiments, silver particles, silver coated copper particles, silver coated aluminum particles, silver plated nickel particles, nickel coated graphite particles, and graphite particles may also be used to make the elastomeric material electrically-conductive.

The at least one electrically-conductive elastomer member 140 may be arranged in any number of configurations, and may be formed integrally or separately from each other. For example, the elastomer rib portions 146 and 148 shown in FIG. 1 may comprise three individual rib portions that are separate from each other, but meet or converge at an intersection point 152. The at least one elastomer rib member 140 may also be configured to be disposed over one or more support ribs 132 formed in the cover 120. In the illustrated embodiment of FIGS. 1 and 2, the electrically-conductive elastomer member 140 has a base portion 150 configured to conform to the contour of the support rib members 132 formed in the cover 120. The electrically-conductive elastomer member 140 has a cross-section that generally reduces in width from the base portion 150 towards an end portion 142.

With further reference to FIG. 1, one example embodiment (FIG. 1) has the electrically-conductive elastomer member 140 configured such that its width at the base portion 152 is about 1.00 millimeter (with a tolerance of +/−0.10 millimeters), which then reduces down to a width 144 of about 0.35 millimeters (with a tolerance of +/−0.10 millimeters) at the end portion 142. Alternatively, the widths of the base portion 150 and end portion 142 may be any suitable size, for example, to provide sufficient compression to attach the cover 120 to the frame 160 while providing adequate contact pressure of the end portion 142 against the at least one electrically-conductive surface.

In some embodiments, the end portion 142 is configured to contact at least one electrically-conductive surface, such as an electrically-conductive trace on a circuit board, etc. In some embodiments, the end portion 142 may also be configured such that it provides for sufficient compression to attach the cover 120 to the frame 160, while also providing adequate contact pressure of the end portion 142 against the at least one electrically-conductive surface.

The at least one electrically-conductive elastomer member 140 is configured (e.g., dimensionally sized, etc.) to have a height H (FIG. 2) greater than the distance between the inner surface 122 of the cover 120 and a circuit board to which the EMI shielding assembly 100 is mounted. In one exemplary embodiment, the electrically-conductive elastomeric member 140 is dimensioned to have a free-standing uncompressed height of about 2.08 millimeters (with a tolerance of +/−0.10 millimeters).

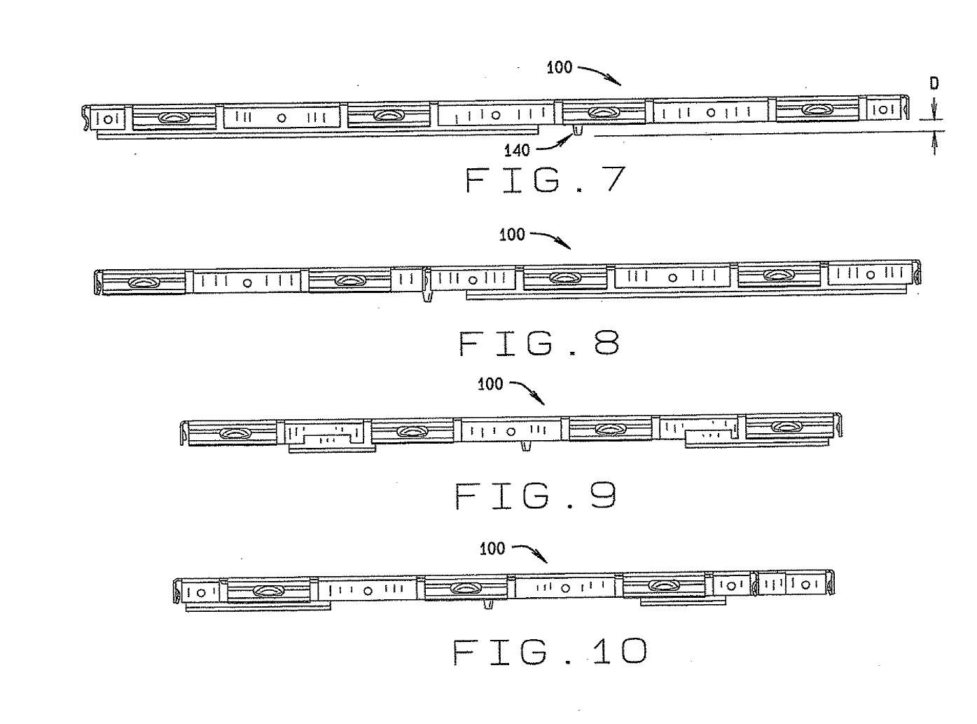

When the cover 120 is secured onto the frame 160, a compressive force can be generated for compressing the electrically-conductive elastomeric member 140 generally between the cover 120 and the electronic component(s) or electrically-conductive surface, to provide a contact pressure effective for establishing at least a minimally sufficient level of electrical conductivity between the electrically-conductive elastomeric member 140 and the electronic component or substrate. The height D (as shown in FIG. 7) associated with the at least one electrically-conductive member 140 allows for compression of the electrically-conductive member 140 against at least one electrically-conductive surface (e.g. a circuit board trace, etc.) when the cover 120 is attached to the frame 160.

In some embodiments, compression of the electrically-conductive member 140 establishes an electrical conductivity between the cover 120 and the at least one electrically-conductive surface that is at least minimally sufficient for EMI shielding applications. In some embodiments, the compression may be sufficient for provides an effective amount of contact pressure to establish a desirable (or even optimal in some embodiments) electrical conductivity. The contact pressure between the electrically-conductive flexible member 140 and the at least one electrically-conductive surface may be sufficient for establishing at least minimally sufficient (and in some embodiments, excellent or desirable) electrical conductivity.

In some embodiments, compression of the electrically-conductive member 140 establishes an electrical conductivity between the cover 120 and the at least one electrically-conductive surface such that the volume resistivity was not more than 0.012 ohm-centimeters (Ω-cm) as measured by mil-dtl-83528C. Alternative embodiments are also possible in which the volume resistivity is greater or lower than 0.012.

In some embodiments, the elastomer rib members 140 may also be thermally conductive (e.g., have a thermal conductivity coefficient greater than that of air alone, etc.) for creating a thermally-conducting heat path from the assembly 100 to a board or substrate (e.g., a printed circuit board, etc.). In such embodiments, the elastomer rib members 140 may be configured to contact at least one electrically-conductive surface on the board from which to conduct heat, such as a trace or a board-mounted electrical component. With this contact, the elastomer rib members 140 may facilitate transferring and/or thermally conducting of heat from the at least one electrically-conductive surface to the cover 120.

A wide variety of materials may be used for a thermal interface, which are preferably better thermal conductors and have higher thermal conductivities than air alone. Accordingly, the thermal interface (with its compressive contact against the electrical component) may thus allow for improved heat transfer from the electrical component to the cover 120 as compared to those designs relying solely upon air to define the heat path between the electrical component and the underside of the cover. Some embodiments include a thermal interface formed from T-flex™ 600 series thermal gap filler material, which is commercially available from Laird Technologies, Inc. of Saint Louis, Mo. In one particular preferred embodiment, a thermal interface comprises T-flex™ 620 thermal gap filer material, which generally includes reinforced boron nitride filled silicone elastomer. By way of further example, other embodiments include thermal interfaces molded from electrically-conductive elastomer. Additional exemplary embodiments include thermal interface materials formed from ceramic particles, ferrite EMI/RFI absorbing particles, metal or fiberglass meshes in a base of rubber, gel, grease or wax, etc. Other suitable thermal interface materials are set forth in the table below. Alternative embodiments, however, may provide an assembly that does not include any such thermal interfaces.

In another aspect of the present disclosure, the elastomer rib members 140 may intervene between one or more areas on a circuit board to partition one or more areas from other areas. The one or more areas partitioned by the elastomer rib members 140 may cooperatively form or define at least one EMI shielding compartment or enclosure. The elastomer rib members 140 may provide for an attenuation of transfer of electromagnetic (EMI) energy for each of the one or more partitioned areas, where that attenuation is at least minimally sufficient for EMI shielding applications.

The elastomer rib members 140 form partition walls that define a predetermined number of shielding compartments or enclosures, where the partition walls that separate the compartments are formed entirely by the elastomer material, independent of the shield cover 120. Accordingly, the cover 120 is free of any integrally formed partition walls that define an enclosure or compartment, such that the cover 120 may be partitioned or divided into a predetermined number of compartments solely by the elastomer rib members 140. The elastomer rib member 140 may be formed to provide any desired arrangement or configuration of compartment spaces, such that a single shield cover design may be tailored or customized to provide various shielded compartment configurations without having to modify the shield cover design or tooling. In the illustrated embodiment shown in FIG. 4, the apparatus 100 has an elastomer rib member 140 having first and second elastomer rib portions 146, 148. The first elastomer rib portion 146 partitions at least a portion of the cover 120 into first and second areas. The second elastomer rib portion 148 is generally perpendicular to the first elastomer rib portion 146, to thereby define at least three compartments 136, 137, and 138. Alternative embodiments may include first and elastomer rib portions that are not perpendicular to each other.

The positioning of the rib member 140 (and rib portions 146 and 148 thereof) onto the cover 120, and the electrically-conductive elastomer member 140 may accordingly provide partitioned areas defined by the assembly 100 that provide EMI shielding of one or more electrical components located within each partitioned area.

Referring to FIG. 4, the elastomer rib member 140 may alternatively be made to form rib 148 and to omit rib 146, to divide the cover area into only two compartment spaces. Similarly, the elastomer rib member 140 may alternatively be made to form rib 146 and only half of rib 148 from point 152, so as to provide only two compartment spaces. Likewise, the elastomer member 140 may include additional rib members (not shown) that would partition the three compartment areas shown in FIG. 4 into additional compartment areas. The above examples illustrate that the elastomer rib members 140 define walls in which the cross-section of the walls are formed entirely by the elastomer material, such that the cover may be partitioned into one or more compartment areas corresponding to one or more areas on a circuit board that the shield is intended to cover.

Circuit board components may often be rearranged to provide various circuit board layouts within the same overall perimeter, and may provide a number of different circuit board types corresponding to various product types or models. Accordingly, exemplary embodiments disclosed herein include a cover that has a fixed perimeter and is free of any partition walls, where the cover may be partitioned into a number of shielding compartments within the cover's fixed perimeter by the application of the elastomer rib members 140 in any desired configuration. Advantageously, this may thus allow a cover (e.g., 120, etc.) to be tailored to provide a number of different shielding configurations corresponding to a number of different circuit board layouts, by the elastomer rib members 140 disposed on the cover, such as through an over-molding process.

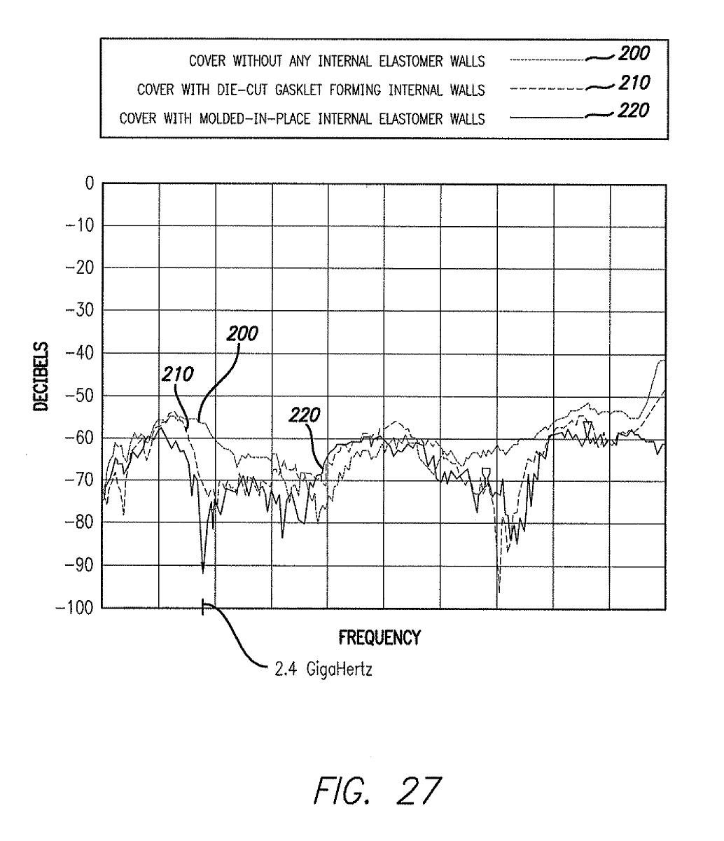

In some embodiments, the elastomer rib members 140 have been shown to attenuate EMI radiation by at least fifteen decibels. Referring to FIG. 27, there is a exemplary line graph illustrating attenuation of EMI radiation versus frequency for three different EMI shielding apparatus, including a cover without any internal elastomer walls (line 200), a cover with die-cut gasket material forming internal walls (line 210), and a cover having overmolded or molded-in-place internal elastomer walls (line 220). This testing and results depicted in FIG. 27 are provided for purpose of illustration only and not for purposes of limitations, as other embodiments may be configured to provide different levels of attenuation than what is shown in FIG. 27.

With continued reference to FIG. 27, it is believed that the one or more elastomer rib members 140, when positioned to intervene between one or more areas of a circuit board, form partition walls defined by the at least one resilient electrically-conductive member effective at reducing the transfer of electromagnetic energy through the cover and resilient electrically-conductive member. Testing of a cover including the elastomer rib members 140 forming interior partition walls (line 220) has shown a reduction in EMI radiation and an attenuation improvement of at least fifteen decibels when compared to a cover without interior partition walls (line 200). Accordingly, the graph generally shows that the shielding performance of the cover 120 with the molded-in-place elastomer rib members 140 performed better in the 2.4 Gigahertz frequency range than the die-cut gasket used to form internal walls. It is believed that the improved attenuation of the molded-in-place elastomer rib members 140 is the result of the molded-in-place elastomer rib members 140 establishing better electrical conductivity between the cover and elastomer rib material than Die-Cut gasket designs. Compared to the cover alone (which achieved a negative fifty-five decibel level), or the cover with die-cut gasket (which achieved a negative seventy four decibel level), the cover with molded-in-place interior elastomer walls achieved a negative eighty decibel level at 2.4 Gigahertz. This 2.4 Gigahertz frequency range is an especially important range for transmission via Bluetooth equipment (Bluetooth is a registered trademark of Bluetooth SIG, Inc.). Accordingly, a cover 120 having a fixed perimeter may have elastomer rib members 140 molded-in-place or over-molded in any desired configuration onto the cover 120 to form a plurality of interior partition walls defining a plurality of shielding compartments, to provide for tailoring a number of different shielding configurations corresponding to a number of different circuit board layouts while also providing improved attenuation of EMI. For example, first and second covers both having the same cover configuration (e.g., stamped pattern, etc.) may be provided with elastomer rib members that are molded-in-place or over-molded to the first and second covers. But the first and second covers need not be provided with elastomer rib members in an identical manner. Instead, the first cover may be provided with one or more elastomer rib members such that interior partition walls and shielding compartments defined thereby are in a different arrangement than that associated with the second cover. Accordingly, this allows the same cover configuration to be tailored or customized by way of the elastomer rib members (and the interior partition walls and compartment defined thereby) for different shielding configurations.

The at least one electrically-conductive elastomer member 140 also provides for contact with a reduced area (or minimum area in some embodiments) electrically-conductive surface. In one exemplary embodiment, the area of contact between the member 140 and electrically-conductive surface is about six millimeters². Having a reduced contact area with the electrically-conductive surface (such as circuit board traces, etc.) may help to reduce or provide a relatively low and acceptable level of electrical impedance between the electrically-conductive surface and the cover.

In an alternate construction of the electrically-conductive elastomer member 140, the member 140 may be formed of silicone-based elastomer with a cross-section that reduces in width from a base portion 152 to an end portion 142. The elastomer member 140 may further comprise electrically-conductive material disposed on the exterior surface of the elastomer member 140. In this alternative embodiment, the at least one electrically-conductive elastomeric member 140 may be disposed or affixed on the inner side 122 of the cover 120 by an adhesive (or via any other suitable attachment means) that bonds the electrically-conductive elastomeric member 140 to the cover 120.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features of the present disclosure and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the methods and the steps, processes, and operations thereof described herein are not to be construed as necessarily requiring their performance in the particular order discussed or illustrated, unless specifically identified as an order of performance. It is also to be understood that additional or alternative steps may be employed.

The description of the disclosure is merely exemplary in nature and, thus, variations that do not depart from the gist of the disclosure are intended to be within the scope of the disclosure. Such variations are not to be regarded as a departure from the spirit and scope of the disclosure.

What is claimed is:

1. An assembly suitable for providing EMI shielding and electrical conduction, the assembly comprising:
a frame adapted to be secured to a mounting surface;
a cover attachable to the frame; and
at least one resilient electrically-conductive member disposed on an inner side of the cover, the at least one resilient electrically-conductive member forming at least one interior partition wall dimensioned for contacting at least one electrically-conductive surface on the mounting surface to establish a current-conducting path from the at least one electrically-conductive surface to the cover when the cover is attached to the frame, wherein the at least one interior partition wall defines a plurality of shielding compartments, and wherein the at least one interior partition wall is formed entirely by the at least one resilient electrically-conductive member independent of the cover.

2. The assembly of claim 1, wherein the at least one interior partition walls formed by the at least one resilient electrically-conductive member are formed to have portions of varying height.

3. The assembly of claim 1, wherein when the cover is attached to the frame, the at least one resilient electrically-conductive member is compressed against the at least one electrically-conductive surface to provide a contact pressure for establishing an electrical conductivity between the cover and the at least one electrically-conductive surface that is sufficient for EMI shielding applications with a volume resistivity equal to less than about 0.012 ohm-centimeters (Ω-cm) as measured by mil-dtl-83528C.

4. The assembly of claim 1, wherein the at least one resilient electrically-conductive member intervenes between one or more areas partitioned by the at least one resilient electrically-conductive member, to form one or more partitions effective to reduce the transfer of electromagnetic energy through the cover and resilient electrically-conductive member so as to provide an attenuation of at least negative ten decibels.

5. The assembly of claim 1, wherein the at least one resilient electrically-conductive member comprises silicone-based elastomer and electrically-conductive particles dispersed within the silicone-based elastomer.

6. An assembly suitable for providing EMI shielding and electrical conduction, the assembly comprising:
a frame adapted to be secured to a mounting surface;
a cover attachable to the frame, said cover being free of any integrally-formed interior partition walls that define any compartments therein; and
at least one flexible electrically-conductive member disposed on an inner side of the cover, the at least one flexible electrically-conductive member forming a plurality of interior partition walls formed on the interior of the cover and defining a plurality of shielding compartments, said interior partition walls being formed entirely by said flexible electrically-conductive material and having a free-standing height greater than a height of the cover such that the flexible electrically-conductive member may be compressed against at least one electrically-conductive surface on the mounting surface when the cover is attached to the frame with an effective amount of contact pressure against the at least one electrically-conductive surface to establish at least a predetermined electrical conductivity between the cover and the at least one electrically-conductive surface on the mounting surface.

7. The assembly of claim 6, wherein the at least one flexible electrically-conductive member is molded-in-place on the interior of the cover.

8. The assembly of claim 7, wherein the at least one flexible electrically-conductive member forms one or more interior partition walls that are positioned to intervene between one or more areas and effective to reduce the transfer of electromagnetic energy through the plurality of one or more interior partition walls and the cover, and provide an improvement in attenuation of at least six decibels at a frequency of 2.4 Gigahertz when compared to a cover having die-cut interior walls.

9. The assembly of claim 6, wherein the at least one flexible electrically-conductive member comprises silicone-based elastomer and electrically-conductive particles dispersed within the silicone-based elastomer.

10. The assembly of claim 6, wherein the plurality of interior partition walls are formed to have portions of varying height.

11. An EMI shield assembly suitable for providing EMI shielding and electrical conduction, the assembly comprising:
an electrically-conductive frame having one or more side walls adapted to be secured to a mounting surface, the one or more side walls including one or more protuberances and/or retaining apertures;
an electrically-conductive cover having one or more side walls with one or more protuberances and/or retaining apertures configured for engaging the corresponding protuberances or retaining apertures of the frame, to thereby releasably attach the cover to the frame, said cover being free of any integrally-formed interior partition walls that define any compartment spaces therein; and
at least one electrically-conductive elastomeric member molded-in-place on an inner side of the cover and forming a plurality of partition walls on the interior of the cover for defining a plurality of shielding compartment spaces, said partition walls being formed entirely by the electrically-conductive elastomeric material independent of the cover, and being dimensioned such that the at least one electrically-conductive elastomeric member is compressed against at least one electrically-conductive surface on the mounting surface when the cover is attached to the frame.

12. The assembly of claim 11, wherein the at least one electrically-conductive elastomeric member is dimensioned to have a free-standing uncompressed height of about 2.08 millimeters.

13. The assembly of claim 11, wherein the at least one electrically-conductive elastomeric member is dimensioned to have a free-standing uncompressed height greater than the distance separating the cover's inner side and the at least one electrically-conductive surface on the mounting surface when the frame is secured to the mounting surface and the cover is attached to the frame.

14. The assembly of claim 11, wherein the at least one electrically-conductive elastomeric member intervenes between one or more areas partitioned by the at least one electrically-conductive member, such that the assembly provides for shielding the transfer of electromagnetic energy from each partitioned area.

15. The assembly of claim 11, wherein the at least one electrically-conductive elastomeric member is molded onto the cover to form one or more interior partition walls that are positioned to intervene between one or more areas, wherein said one or more interior partition walls are defined by the at least one electrically-conductive elastomeric member are effective to reduce the transfer of electromagnetic energy at a frequency of 2.4 Gigahertz through the one or more interior partition walls and the cover to provide an improvement in attenuation of at least six decibels when compared to a comparable cover having die-cut interior walls.

16. The assembly of claim 11, wherein the at least one electrically-conductive elastomeric member comprises a first electrically-conductive elastomeric portion generally perpendicular to at least a second electrically-conductive elastomeric portion to partition the area being covered by the assembly into three areas to provide an improvement in attenuation of the transfer of electromagnetic energy through the cover and the resilient electrically-conductive portions of at least six decibels when compared to a comparable cover having die-cut interior walls.

17. The assembly of claim 11, wherein the at least one electrically-conductive elastomeric member has a cross-section that reduces in width from a base portion to a free end portion.

18. The assembly of claim 17, wherein the at least one electrically-conductive elastomeric member has a cross-section that reduces towards the area of contact with the at least one electrically-conductive surface, and wherein the free end of the at least one electrically-conductive elastomeric member has a width of about 0.35 millimeters or less.

19. The assembly of claim 11, wherein the at least one electrically-conductive elastomeric member comprises a silicone-based elastomer matrix and electrically-conductive particles dispersed within the silicone-based elastomer matrix, and wherein the electrically-conductive particles comprise metal coated glass spheres dispersed within the silicone-based elastomer matrix.

20. The assembly of claim 21, wherein the interior partition walls formed by the electrically-conductive elastomeric member are formed to have portions of varying height.

21. The assembly of claim 11, wherein the at least one electrically-conductive elastomeric member has a cross-section that reduces in width from a base portion to an end portion, and wherein the at least one electrically-conductive elastomeric member comprises an electrically-conductive material disposed on an exterior surface of an inner elastomeric member.

22. The assembly of claim 11, wherein when the cover is attached to the frame, the at least one electrically-conductive elastomeric member is compressed against the at least one electrically-conductive surface to provide a contact pressure for establishing an electrical conductivity between the cover and the at least one electrically-conductive surface on the mounting surface that is sufficient for EMI shielding applications with a volume resistivity equal to less than about 0.012 ohm-centimeters (Ω-cm) as measured by mil-dtl-83528C.
